(19) United States
(12) Patent Application Publication
(10) Pub. No.: US 2023/0309349 A1
(43) Pub. Date: Sep. 28, 2023

(54) ELECTRO-OPTICAL DEVICE AND ELECTRONIC APPARATUS

(71) Applicant: SEIKO EPSON CORPORATION, Tokyo (JP)

(72) Inventor: Takumi KODAMA, Chino-shi (JP)

(73) Assignee: SEIKO EPSON CORPORATION, Tokyo (JP)

(21) Appl. No.: 18/125,383

(22) Filed: Mar. 23, 2023

(30) Foreign Application Priority Data
Mar. 24, 2022 (JP) 2022-047761

(51) Int. Cl. H10K 59/126; G02B 27/01; H10K 59/38

(52) U.S. Cl. CPC H10K 59/126; G02B 27/0172; H10K 59/38; G02B 2027/0178; G02B 30/22

(57) ABSTRACT

An electro-optical device includes a substrate having a rectangular shape in plan view, a display unit provided with an OLED at the substrate, inspection terminals provided between the display unit and an upper side on an opposite side from a lower side in plan view at the substrate, and a light shielding member provided so as to cover the inspection terminals in plan view.

The present application is based on, and claims priority from JP Application Serial Number 2022-047761, filed Mar. 24, 2022, the disclosure of which is hereby incorporated by reference herein in its entirety.

### BACKGROUND

### 1. Technical Field

The present disclosure relates to an electro-optical device and an electronic apparatus.

### 2. Related Art

An electro-optical device using an organic light emitting diode (OLED), for example, is known as a light-emitting element. In an electro-optical device, sub-pixels or pixels are arrayed in a display unit, and in the sub-pixel or the pixel, a light-emitting element, a transistor for causing a current to flow into the light-emitting element, and the like are provided. Further, a peripheral circuit and a peripheral wiring for driving the sub-pixels or the pixels are provided outside the display unit.

When light is incident from an observation side, the light may be reflected at a peripheral wiring or the like and visually recognized by an observer as reflection. Thus, a technique for shielding the peripheral wiring from light has been known (see, for example, JP-A-2018-78110).

However, in recent years, a wide visual field angle has been required for an electro-optical device 10, which leads to the occurrence of reflection of a portion other than the peripheral wiring.

### SUMMARY

An electro-optical device according to an aspect of the present disclosure includes a substrate having a rectangular shape in plan view, a display unit provided with a light-emitting element at the substrate, a plurality of first inspection terminals provided, in plan view, between the display unit and a second side opposite that is on an opposite side of the rectangular shape from a first side, at the substrate, and a light shielding member provided so as to cover the plurality of first inspection terminals in plan view.

### BRIEF DESCRIPTION OF THE DRAWINGS

FIG. 1 is a perspective view illustrating an electro-optical device according to a first embodiment.

FIG. 2 is a block diagram illustrating an electrical configuration of the electro-optical device.

FIG. 3 is a block diagram illustrating a configuration of a pixel circuit in the electro-optical device.

FIG. 4 is a timing chart for describing an operation of the electro-optical device.

FIG. 5 is a plan view illustrating an arrangement of inspection terminals and the like in the electro-optical device.

FIG. 6 is a diagram illustrating an example of electrical coupling of the inspection terminals in the electro-optical device.

FIG. 7 is a plan view illustrating an arrangement of a light shielding member in the electro-optical device.

FIG. 8 is a cross-sectional view of the electro-optical device taken along an A-A′ line in FIG. 7.

FIG. 9 is a cross-sectional view of a main portion of the electro-optical device taken so as to include the inspection terminals.

FIG. 10 is a plan view illustrating an alignment mark of the electro-optical device.

FIG. 11 is a cross-sectional view of a main portion of the electro-optical device taken so as to include the alignment mark.

FIG. 12 is a plan view illustrating a positional relationship between the inspection terminal and the light shielding member.

FIG. 13 is a plan view illustrating an arrangement of elements in an electro-optical device according to a second embodiment.

FIG. 14 is a perspective view illustrating a head-mounted display using an electro-optical device.

FIG. 15 is a diagram illustrating an optical configuration of the head-mounted display.

FIG. 16 is a plan view illustrating an arrangement of a light shielding member in an electro-optical device according to a comparative example.

### DESCRIPTION OF EXEMPLARY EMBODIMENTS

An electro-optical device according to an embodiment of the present disclosure will be described below with reference to the accompanying drawings. In each of the drawings, dimensions and scale of each part are appropriately different from actual ones. Moreover, the embodiment, which will be described below, is a suitable specific example, and various technically preferable limitations are applied, but the scope of the disclosure is not limited to these modes unless they will be specifically described in the following description as limiting the disclosure.

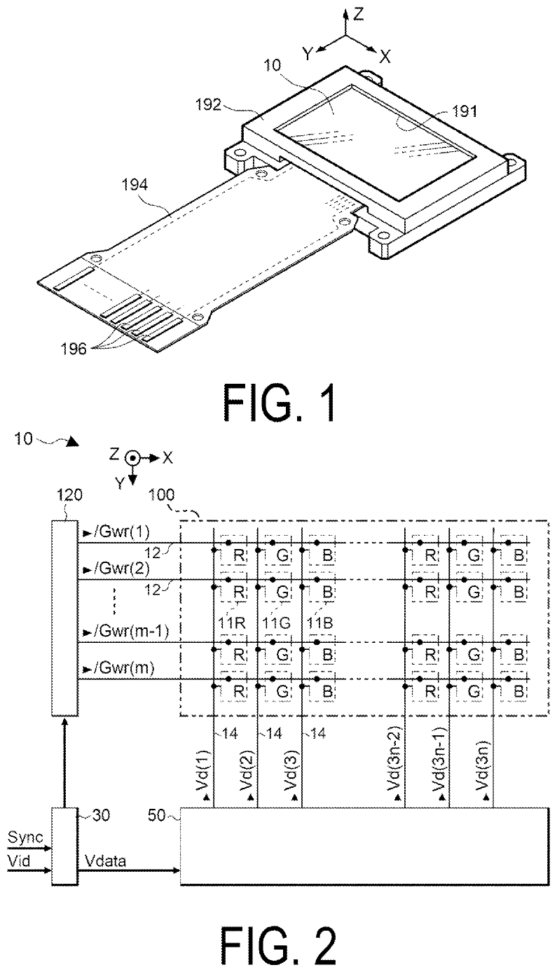

FIG. 1 is a perspective view illustrating an exterior of an electro-optical device 10. The electro-optical device 10 is a micro display panel that displays a video, for example, in a head-mounted display or the like. The electro-optical device 10 includes a plurality of sub-pixels, a driving circuit that drives the sub-pixels, and the like. The sub-pixels and the driving circuit are integrated into a semiconductor substrate. The semiconductor substrate is typically a silicon substrate, but may be a different semiconductor substrate.

As illustrated in the figure, the electro-optical device 10 is accommodated in a case 192 having a frame shape and including an opening portion 191. One end of a flexible printed circuit (FPC) substrate 194 is coupled to the electro-optical device 10. A plurality of terminals 196 are provided at the other end of the FPC substrate 194. The plurality of terminals 196 are coupled to a host device (not illustrated). The host device supplies video data and various control signals to the electro-optical device 10 via the FPC substrate 194.

Note that in the drawings, an X direction indicates a longitudinal direction of a display image in the electro-optical device 10, and a Y direction indicates a lateral direction of the display image. Additionally, a two-dimensional plane defined by the X direction and the Y direction is a substrate surface of a semiconductor substrate. A Z direction is perpendicular to the X direction and the Y direction, and indicates an emission direction of light emitted from an OLED, which will be described below.

FIG. 2 is a diagram illustrating an electrical configuration of the electro-optical device 10. The electro-optical device 10 is substantially divided into a control circuit 30, a data signal output circuit 50, a display unit 100, and a scanning line drive circuit 120.

In the display unit 100, scanning lines 12 of m rows are provided along the X direction in the figure, and data lines 14 of (3n) columns are provided along the Y direction so as to be electrically insulated from the respective scanning lines 12. Each of m and n is an integer equal to or greater than 2.

To distinguish the rows from each other in the scanning lines 12, the rows may be referred to as first, second, third, . . . , (m−1)-th, and m-th rows in order from the top in the figure. Note that in order to generally describe the scanning line 12 without specifying the row, the scanning line 12 may be denoted as an i-th row by using an integer i equal to or larger than 1 and equal to or smaller than m.

Further, to distinguish the columns from each other in the data lines 14, the columns may be referred to as first, second, third, . . . , (3n−2)-th, (3n−1)-th, and (3n)-th columns in order from the left in the figure. Note that the data lines 14 are grouped for every three columns. When an integer j equal to or larger than 1 and equal to or smaller than n is used to generalize and describe the group, three columns in total of the data lines 14 of (3j−2)-th, (3j−1)-th, and (3j)-th columns belong to a j-th group counted from the left.

Sub-pixels 11R, 11G, and 11B are provided corresponding to the scanning lines 12 arrayed in m rows and the data lines 14 arrayed in (3n) columns. Specifically, the sub-pixel 11R is provided corresponding to an intersection between the scanning line 12 of the i-th row and the data line 14 of the (3j−2)-th column. The sub-pixel 11G is provided corresponding to an intersection between the scanning line 12 of the i-th row and the data line 14 of the (3j−1)-th column. The sub-pixel 11B is provided corresponding to an intersection between the scanning line 12 of the i-th row and the data line 14 of the (3j)-th column.

The sub-pixel 11R emits light having a red color component, the sub-pixel 11G emits light having a green color component, and the sub-pixel 11B emits light having a blue color component. One color pixel is expressed by additive color mixing of light emitted from the sub-pixels 11R, 11B, and 11G. Note that the sub-pixels 11R, 11G, and 11B have the same electrical configuration. Thus, when the sub-pixels do not need to be particularly distinguished from each other, the sub-pixels will be described with a reference sign of 11.

The control circuit 30 controls each portion based on video data Vid and a synchronization signal Sync that are supplied from the host device, which is not illustrated. Specifically, the control circuit 30 generates various control signals to control each portion.

The video data Vid designates, for example, a gray scale level in a pixel to be displayed by 8 bits for each of red, green, and blue. The synchronization signal Sync includes a vertical synchronization signal that instructs a start of vertical scanning of the video data Vid, a horizontal synchronization signal that instructs a start of horizontal scanning, and a dot clock signal that indicates a timing of one pixel of the video data.

In the present embodiment, a pixel to be displayed and one color pixel expressed by three sub-pixels in the display unit 100 correspond one-to-one with each other. In addition, a luminance characteristic at the gray scale level indicated by the video data Vid supplied from the host device and a luminance characteristic in the OLED included in the sub-pixel 11 do not necessarily coincide with each other. Thus, to make the OLED emit light at a luminance corresponding to the gray scale level indicated by the video data Vid, the control circuit 30 up-converts 8 bits of the video data Vid into, for example, 10 bits and outputs the up-converted 10-bit data as video data Vdata. Thus, the 10-bit video data Vdata is data corresponding to the gray scale level designated by the video data Vid.

Note that a look-up table in which a correspondence relationship between the 8 bits of the video data Vid that is the input and the 10 bits of the video data Vdata that is the output is stored in advance is used in the up-conversion.

The scanning line drive circuit 120 is a circuit for driving the sub-pixels 11 arrayed in m rows and (3n) columns for each row in accordance with control by the control circuit 30. For example, the scanning line drive circuit 120 supplies scanning signals /Gwr(1), /Gwr(2), . . . , /Gwr(m−1), and /Gwr(m) to the scanning lines 12 of first, second, third, . . . , (m−1)-th, and m-th rows in order. The scanning signal supplied to the scanning line 12 in the i-th row is denoted as/Gwr(i) in general.

A data signal output circuit 50 is a circuit that outputs data signals to the sub-pixels 11 positioned in a row selected by the scanning line drive circuit 120 through the data lines 14 in accordance with the control of the control circuit 30. The data signals are voltage signals where the 10-bit video data Vdata is converted into analog signals. In other words, the data signal output circuit 50 converts the video data Vdata of one row corresponding to the sub-pixels 11 of first to (3n)-th columns in the selected row into analog signals, and outputs the analog signals to the data lines 14 of the first to (3n)-th columns in this order.

In the drawings, the data signals output to the data lines 14 of the first, second, third, . . . , (3n−2)-th, (3n−1)-th, and (3n)-th columns are denoted as Vd(1), Vd(2), Vd(3), . . . , Vd(3n−2), Vd(3n−1), and Vd(3n). A data signal supplied to the data line 14 in the j-th column is denoted as Vd(j) in general.

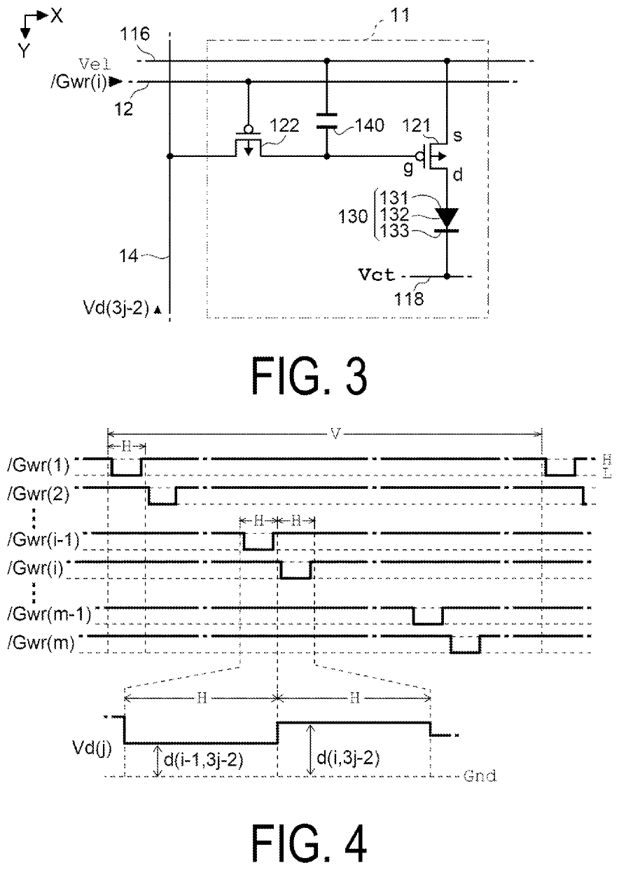

FIG. 3 is a circuit diagram illustrating an electrical configuration of the sub-pixel 11. As illustrated in the figure, the sub-pixel 11 includes P-channel MOS type transistors 121 and 122, an OLED 130, and a capacitance element 140 from an electrical point of view.

Note that in the description of the sub-pixel 11, the expression “an electrical point of view” is used when a plurality of elements constituting the sub-pixel 11 and coupling relationships between the plurality of elements are described. The sub-pixel 11 includes elements that do not contribute to the electrical coupling relationship from a mechanical or physical point of view, so that such an expression is used.

The OLED 130 is an example of a light-emitting element in which a light-emitting layer 132 is interposed between a pixel electrode 131 and a common electrode 133. The pixel electrode 131 functions as an anode, and the common electrode 133 functions as a cathode. In the OLED 130, when a current flows from the anode to the cathode, holes injected from the anode and electrons injected from the cathode are recombined in the light-emitting layer 132 to generate excitons, and white light is generated.

The generated white light resonates in an optical resonator constituted by a reflection electrode and a semi-reflective and semi-transmissive layer that are omitted in FIG. 3, and for example, in the sub-pixel 11R, is emitted at a resonant wavelength set corresponding to a red color. A color layer (color filter) corresponding to the red color is provided at an emission side of the light from the optical resonator. Thus, the emitted light from the OLED 130 is visually recognized by an observer through the optical resonator and the color layer.

Note that in a case of the sub-pixel 11G, light is emitted at a resonant wavelength set corresponding to a green color, and is visually recognized by the observer through the color layer corresponding to the green color, and in a case of the sub-pixel 11B, light is emitted at a resonant wavelength set corresponding to a blue color, and is visually recognized by the observer through the color layer corresponding to the blue color.

In the transistor 121 of the sub-pixel 11 at the i-th row and the (3j−2)-th column, a gate node g is coupled to a drain node of the transistor 122, a source node is coupled to a power supplying line 116 of a voltage Vel, and a drain node is coupled to the pixel electrode 131 that is an anode of the OLED 130.

In the transistor 122 of the sub-pixel 11 at the i-th row and the (3j−2)-th column, a gate node is coupled to the scanning line 12 of the i-th row, and a source node is coupled to the data line 14 of the (3j−2)-th column. The common electrode 133 that functions as a cathode of the OLED 130 is coupled to a power supplying line 118 of a voltage Vct. Further, since the electro-optical device 10 is formed on a silicon substrate, a substrate potential of each of the transistors 121 and 122 is set to a potential corresponding to, for example, the voltage Vel.

FIG. 4 is a timing chart for describing an operation of the electro-optical device 10.

In the electro-optical device 10, the scanning lines 12 of m rows are scanned one by one in the order of first, second, third, . . . , and m-th rows during a period of a frame (V). Specifically, as illustrated in the figure, the scanning signals/Gwr(1), /Gwr(2), . . . , /Gwr(m−1), and/Gwr (m) successively and exclusively reach an L level for each horizontal scanning period (H) by the scanning line drive circuit 120.

In the present embodiment, a period during which the adjacent scanning signals among the scanning signals/Gwr(1) to /Gwr(m) reach the L level is temporally isolated. Specifically, after the scanning signal/Gwr(i−1) changes from the L level to a H level, the next scanning signal/Gwr(i) reaches the L level after a period of time. This period corresponds to a horizontal blanking period.

In the present description, the period of one frame (V) refers to a period required to display one frame of an image designated by the video data Vid. In a case in which a length of the period of one frame (V) is the same as a vertical synchronization period, for example, when a frequency of a vertical synchronization signal included in a synchronization signal Sync is 60 Hz, the length is 16.7 milliseconds that corresponds to one cycle of the vertical synchronization signal. In addition, the horizontal scanning period (H) is an interval of time in which the scanning signals/Gwr(1) to/Gwr(m) reach the L level in order, but in the figure, for convenience, a start timing of the horizontal scanning period (H) is approximately a center of the horizontal blanking period.

When a certain scanning signal among the scanning signals/Gwr(1) to/Gwr(m), for example, the scanning signal /Gwr(i) supplied to the scanning line 12 in the i-th row reaches the L level, in a case of the (3j−2)-th row, the transistor 122 in the sub-pixel 11 at the i-th row and the (3j−2)-th column is turned into an on state. Thus, the gate node g of the transistor 121 in the sub-pixel 11 is electrically coupled to the data line 14 in the (3j−2)-th column.

Note that in the present description, the “on state” of a transistor or a switch means that a part between the source node and the drain node in the transistor or both ends of the switch is electrically closed to be turned into a low impedance state. Also, an “off state” of the transistor or the switch means that a part between the source node and the drain node or the both ends of the switch are electrically opened to be turned into a high impedance state.

Also, in the description, “electrically coupled” or simply “coupled” means a state in which two or more elements are directly or indirectly coupled or bonded. “Electrically non-coupled” or simply “non-coupled” means a state in which the two or more elements are not directly or indirectly coupled or not bonded.

In the horizontal scanning period (H) in which the scanning signal/Gwr(i) reaches the L level, the data signal output circuit 50 converts the gray scale levels of the sub-pixels from the i-th row and the first column to the i-th row and the (3n)-th column that are indicated by the video data Vdata into analog data signals Vd(1) to Vd(n), and outputs the converted analog data signals Vd(1) to Vd(n) to the data lines 14 in the first to (3n)-th columns. In the (3j−2)-th column, the data signal output circuit 50 converts the gray scale level d(i, 3j−2) of the pixel at the i-th row and the (3j−2)-th column into the analog data signal Vd(j), and outputs the converted analog data signal Vd(j) to the data line 14 in the (3j−2)-th column.

Note that in the horizontal scanning period (H) in which the scanning signal/Gwr(i−1) that is one line before the scanning signal/Gwr(i) reaches the L level, the data signal output circuit 50 converts the gray scale level d(i−1, 3j−2) of the sub-pixel 11 at the (i−1)-th row and the (3j−2)-th column into the data signal Vd(3j−2) of the analog signal, and outputs the converted data signal Vd(3j−2) to the data line 14 in the (3j−2)-th column.

The data signal Vd (3j−2) is supplied to the gate node g of the transistor 121 in the sub-pixel 11 at the i-th row and the (3j−2)-th column through the data line 14 in the (3j−2)-th column, and is held by the capacitance element 140. Therefore, the transistor 121 causes a current corresponding to a voltage between the gate node and the source node to flow to the OLED 130.

Even when the scanning signal Gwr(i) reaches a H level and the transistor 122 is turned into an off state, the voltage of the data signal Vd(3j−2) is held at one end of the capacitance element 140, and thus, the current continues to flow in the OLED 130. Thus, in the sub-pixel 11 at the i-th row and the (3j−2)-th column, the OLED 130 continues to emit light with the voltage held by the capacitance element 140, that is, at the luminance corresponding to the gray scale level until the period of one frame (V) elapses and the transistor 122 is turned on again and the voltage of the data signal is applied again.

Note that although the sub-pixel 11 at the i-th row and the (3j−2)-th column has been described here, the OLEDs 130 at the columns other than the (3j−2)-th column in the i-th row also emit light at the luminances indicated by the video data Vdata.

Also, each of the OLEDs 130 of the sub-pixels 11 in the rows other than the i-th row also emits light with the luminance indicated by the video data Vdata by the scanning signals /Gwr(1) to/Gwr(m) reaching the L level in order.

Thus, in the electro-optical device 10, during the period of one frame (V), the OLEDs 130 in all of the sub-pixels 11 from the first row and the first column to the m-th row and the (3n)-th column emit light at the luminances indicated by the video data Vdata, thereby causing an image of one frame to be displayed.

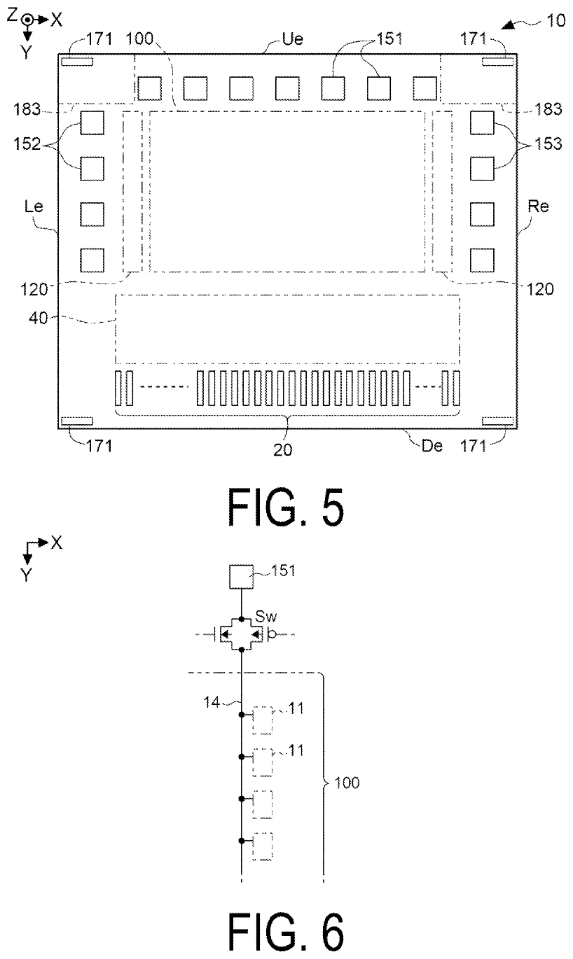

FIG. 5 is a plan view illustrating an arrangement of elements in the electro-optical device 10.

The electro-optical device 10 has a rectangular shape. In the electro-optical device 10 having a rectangular shape, for the sake of convenience, as illustrated in the figure, a sign of the upper side is denoted by Ue, a sign of the lower side is denoted by De, a sign of the left side is denoted by Le, and a sign of the right side is denoted by Re.

Between the lower side De and the display unit 100, a circuit region 40 and a plurality of mounting terminals 20 are provided in this order when viewed from the display unit 100.

Note that the plurality of mounting terminals 20 are provided along the X direction at the lower side De. Additionally, the circuit region 40 is a region collectively representing the control circuit 30 and the data signal output circuit 50 that are illustrated in FIG. 2. The lower side De corresponds to a “first side” in the claims.

The scanning line drive circuit 120 is provided between the left side Le and the display unit 100. Similarly, the scanning line drive circuit 120 is provided between the right side Re and the display unit 100. That is, a pair of the scanning line drive circuits 120 are positioned symmetrically with respect to the display unit 100, and drives the scanning lines 12 from both left and right sides.

As described above, in the configuration in which the scanning lines 12 are driven from the both sides, the influence of a voltage drop due to a signal delay or a wiring resistance is suppressed as compared with the configuration in which the scanning lines 12 are driven from only one side.

Further, peripheral wirings (not illustrated) are provided outside the display unit 100. Examples of the peripheral wirings include a signal wiring for supplying a control signal to the display unit 100, and a power supply wiring.

Further, alignment marks 171 for determining respective positions in a manufacturing process are provided at four corners of the electro-optical device 10.

A plurality of inspection terminals 151 are provided along the X direction between the upper side Ue and the display unit 100. Similarly, a plurality of inspection terminals 152 are provided along the Y direction between the left side Le and the scanning line drive circuit 120, and a plurality of inspection terminals 153 are provided along the Y direction between the right side Re and the scanning line drive circuit 120. Note that the upper side Ue corresponds to a “second side” in the claims, the left side Le corresponds to a “third side” in the claims, and the right side Re corresponds to a “fourth side” in the claims.

The inspection terminal 151 is a terminal for inspecting, for example, an open circuit or a short circuit of the data line 14 in the manufacturing process of the electro-optical device 10. Specifically, as illustrated in FIG. 6, the inspection terminal 151 is electrically coupled to the data line 14 via an analog switch Sw.

After the common electrode 133 is provided, the inspection terminal 151 is covered with an insulating film, but before the inspection, the insulating film is opened with a hole to expose the inspection terminal 151. During the inspection, the analog switch Sw is turned into the on state to bring a probe for inspection into contact with the inspection terminal 151. In this state, when a data signal having a predetermined gray scale level is output to the inspection terminal 151 corresponding to the data line 14 in the (3j−2)-th column, if a data signal having the voltage corresponding to the gray scale level appears, the data line 14 in the (3j−2)-th column is determined to be normal, and if the data signal does not appear, the data line 14 is determined to be abnormal.

Note that although the inspection terminal 151 is used to determine whether the data line 14 is normal or abnormal here, the inspection terminal 151 may be used to inspect, for example, a latching circuit (not illustrated) in the data signal output circuit 50, or the like.

Additionally, the inspection terminals 152 and 153 may also be provided with the analog switches Sw, coupled to the scanning lines 12 and the inside of the scanning line drive circuit 120, and used for inspecting the scanning line drive circuit 120 and the like.

In addition, one inspection terminal 151, 152, or 153 may be provided for each two or more elements of scanning lines 12, data lines 14, control lines, and output lines instead of being provided in one-to-one correspondence with the scanning line 12, the data line 14, or the like.

Such an inspection terminal 151 is provided by patterning a wiring layer in the electro-optical device 10, specifically, a conductive layer made of aluminum or the like. When a visual field angle required for the electro-optical device 10 increases, even in a state in which the electro-optical device 10 is accommodated in the case 192, emitted light from the OLED 130 or incident light from the observation side may be reflected at the inspection terminal 151, captured by an optical system, and visually recognized by the observer.

Thus, in the first embodiment, the color layers of three colors used for the sub-pixels 11 in the display unit 100 are overlapped to cover the inspection terminals 151 provided along the X direction, so that the light reflected at the inspection terminal 151 is hardly visually recognized by the observer.

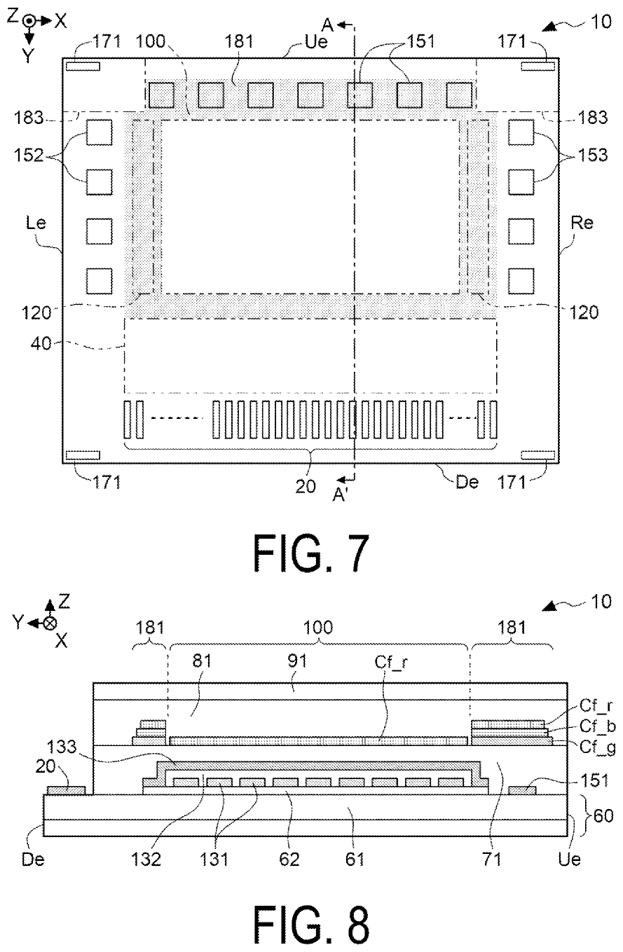

FIG. 7 is a plan view illustrating an arrangement of a light shielding member in the electro-optical device 10, and FIG. 8 is a cross-sectional view schematically illustrating the electro-optical device 10 taken along the A-A′ line in FIG. 7.

The electro-optical device 10 is constituted by a substrate. The substrate constituting the electro-optical device 10 includes a semiconductor substrate 60, the display unit 100, the plurality of mounting terminals 20, the inspection terminals 151, 152, and 153, and color layers Cf_r, Cf_g, and Cf_b. The light shielding member 181 is provided outside the display unit 100 in plan view so as to surround the display unit 100 and cover the inspection terminals 151 arrayed along the X direction. In the present embodiment, the light shielding member 181 refers to a region in which the color layer Cf_g with a green color, the color layer Cf_b with a blue color, and the color layer Cf_r with a red color are layered, and is distinguished from a region constituted by the color layer of one color. The light shielding member 181 has a function of becoming black by subtractive color mixing of green, blue, and red, absorbing incident light, and reducing emitted light.

As illustrated in FIG. 8, a driving circuit layer 61 is provided in the semiconductor substrate 60 that is a substrate constituting the electro-optical device 10 by patterning, ion implantation, or the like. The driving circuit layer 61 includes the transistors 121 and 122 and the capacitance element 140 in the sub-pixel 11, elements constituting the scanning line drive circuit 120, elements constituting the data signal output circuit 50, and the like.

A peripheral wiring layer 62 is provided in the Z direction of the driving circuit layer 61. The peripheral wiring layer 62 is an aggregate layer of wirings that electrically couple various elements in the driving circuit layer 61. Note that the peripheral wiring layer 62 is actually constituted by a plurality of wiring layers with insulating films interposed therebetween. In addition, the inspection terminals 151, 152, and 153 and the mounting terminals 20 are provided by patterning of the wiring layers constituting the peripheral wiring layer 62.

The pixel electrodes 131 constituting the sub-pixels 11 are provided in the Z direction of the peripheral wiring layer 62. As described above, the OLED 130 is configured such that the light-emitting layer 132 is interposed between the pixel electrode 131 and the common electrode 133.

Note that after the common electrode 133 is formed, insulating films, which will be described later, are opened with a hole, and a probe is brought into contact with the inspection terminal 151 to inspect whether or not the data signal output circuit 50, the scanning line drive circuit 120, the scanning line 12, the data line 14, and the like are normally formed.

Since the inspection terminals 151 are not used after the inspection, a sealing layer 71 is provided so as to cover the common electrodes 133 and the inspection terminals 151. Note that the mounting terminals 20 need to be coupled to the FPC substrate 194. Thus, the sealing layer 71 is provided so as to avoid the mounting terminals 20. Additionally, in FIG. 8, the circuit region 40 is omitted.

As described above, in the Z direction of the sealing layer 71, the color layer Cf_g with the green color, the color layer Cf_b with the blue color, and the color layer Cf_r with the red color are provided in this order. In particular, the color layers Cf_g, Cf_b, and Cf_r are provided as the light shielding member 181 so as to surround the display unit 100 at the outside of the display unit 100 and cover the inspection terminals 151 in plan view.

In the display unit 100, the color layer Cf_r is provided corresponding to the sub-pixel 11R, the color layer Cf_g is provided corresponding to the sub-pixel 11G, and the color layer Cf_b is provided corresponding to the sub-pixel 11B. Note that FIG. 8 illustrates a state in which FIG. 7 is taken along the A-A′ line along the Y direction, and thus, only the color layer Cf_r of a specific color, that is, red in this example, is provided in the display unit 100.

A protective glass 91 is provided in the Z direction with respect to the sealing layer 71 and the color layer Cf_g, Cf_b, or Cf_r with an adhesive layer 81 interposed therebetween.

Note that an overcoat layer is provided in order to flatten a step caused by the color layer Cf_g, Cf_b, or Cf_r, but is omitted in FIG. 8.

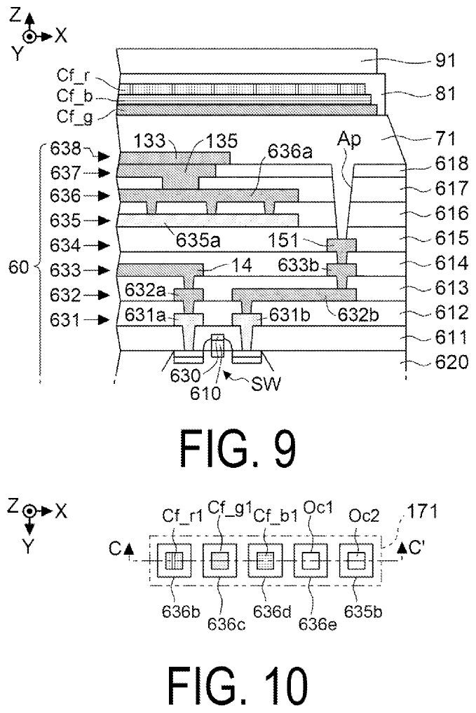

FIG. 9 is a partial cross-sectional view illustrating a more detailed structure near the inspection terminal 151.

In the semiconductor substrate 60 that is the substrate constituting the electro-optical device 10, layers used as conductive layers are a semiconductor layer 620, a gate electrode layer 630, a first wiring layer 631, a second wiring layer 632, a third wiring layer 633, a fourth wiring layer 634, a reflection layer 635, a contact layer 636, a pixel electrode layer 637, and a cathode layer 638 in order toward the Z direction.

As the first wiring layer 631, the second wiring layer 632, the third wiring layer 633, the fourth wiring layer 634, the reflection layer 635, and the contact layer 636, for example, aluminum, an alloy containing aluminum, or the like is used. As the pixel electrode layer 637, for example, indium tin oxide having transmissiveness and conductivity is used. In addition, as the cathode layer 638, metal having transparency, reflectivity, and conductivity, for example, an alloy of Mg and Ag or the like is used.

In the semiconductor layer 620, transistor regions (a source region and a drain region) are provided by, for example, implanting impurity ions into a p-well region Well. A gate insulating film 610 is provided between the semiconductor layer 620 and the gate electrode layer 630.

By patterning the gate electrode layer 630, gate electrodes and the like of various transistors such as the transistors 121 and 122 are provided including the gate electrode of a transistor constituting the analog switch Sw. Note that in FIG. 9, only one of two complementary transistors constituting the analog switch Sw coupled to the inspection terminal 151 is illustrated.

In the first wiring layer 631, the second wiring layer 632, the third wiring layer 633, and the fourth wiring layer 634, wirings, electrodes, and the like are provided by patterning of each layer. In addition, insulating films 611, 612, 613, and 614 are sequentially respectively provided between the gate electrode layer 630 and the first wiring layer 631, between the first wiring layer 631 and the second wiring layer 632, between the second wiring layer 632 and the third wiring layer 633, and between the third wiring layer 633 and the fourth wiring layer 634. The different wiring layers are electrically coupled to each other through contact holes opened in the insulating films.

For example, the source region of the transistor constituting the analog switch Sw is electrically coupled to a wiring 631a formed by patterning the first wiring layer 631 through a contact hole, and the wiring 631a is electrically coupled to a wiring 632a formed by patterning the second wiring layer 632 through a contact hole. Furthermore, the wiring 632a is electrically coupled to the data line 14 formed by patterning the third wiring layer 633 through a contact hole.

In addition, for example, the drain region of the transistor constituting the analog switch Sw is electrically coupled to a wiring 631b formed by patterning the first wiring layer 631 through a contact hole, and the wiring 631b is electrically coupled to a wiring 632b formed by patterning the second wiring layer 632 through a contact hole. Furthermore, the wiring 632b is electrically coupled to the wiring 633b formed by patterning the third wiring layer 633 through a contact hole, and the wiring 633b is electrically coupled to the inspection terminal 151 formed by patterning the fourth wiring layer 634 through a contact hole. Thus, the inspection terminal 151 is coupled to the data line 14 via the analog switch Sw.

Insulating films 615, 616, and 617 are respectively provided in order between the fourth wiring layer 634 and the reflection layer 635, between the reflection layer 635 and the contact layer 636, and between the contact layer 636 and the pixel electrode layer 637, and an insulating film 618 is provided in the Z direction of the insulating film 617.

The reflection layer 635 is used as the reflection electrode of the optical resonator in the display unit 100, and is electrically coupled to the common electrode 133 as a wiring 635a by patterning at the outside of the display unit 100 in plan view to function as a part of parallel wirings for applying the voltage Vel to the common electrode 133. Note that in the display unit 100, the reflection layer 635 is patterned into a shape corresponding to the pixel electrode 131.

The contact layer 636 is a wiring layer for coupling the pixel electrode layer 637 to the reflection layer 635 or the fourth wiring layer 634, and the contact layer 636, as the wiring 636a, is electrically coupled to the wiring 635a through a plurality of contact holes by patterning at the outside of the display unit 100.

The pixel electrode layer 637 is patterned as the pixel electrode 131 for each sub-pixel 11 in the display unit 100, but functions as a part of the wiring for applying the voltage Vel to the common electrode 133 at the outside of the display unit 100.

In the display unit 100, the light-emitting layer 132 is provided between the pixel electrode 131 and the common electrode 133 by the pixel electrode layer 637, but the light-emitting layer 132 is not provided near a portion provided with the inspection terminal 151. Thus, the wiring 135 formed by patterning the pixel electrode layer 637 is in direct contact with the common electrode 133.

Note that an opening portion Ap is provided corresponding to the inspection terminal 151. The opening portion Ap opens the insulating films 615 to 618. In inspecting, a probe is brought into contact through the opening portion Ap, and is used for the inspection. The sealing layer 71 provided so as to cover the common electrode 133 after the inspection is filled in the opening portion Ap.

As described above, the color layer Cf_g with the green color, the color layer Cf_b with the blue color, and the color layer Cf_r with the red color are provided in this order in the Z direction of the sealing layer 71, and the protective glass 91 is further provided with the adhesive layer 81 interposed therebetween.

The alignment marks 171 are provided at four positions in plan view in the electro-optical device 10. The alignment marks 171 provided at the four positions have a common configuration.

Because of this, the alignment mark 171 provided at any one position will be described.

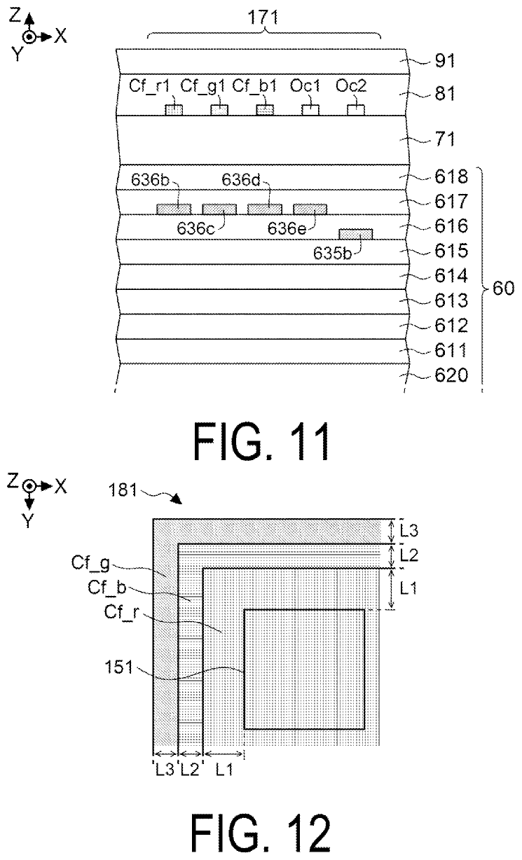

FIG. 10 is a plan view specifically illustrating the alignment mark 171, and FIG. 11 is a cross-sectional view of a main portion of the electro-optical device 10 taken along the C-C′ line in FIG. 10.

As illustrated in FIG. 10, the alignment mark 171 is constituted by a combination of a patterned color layer Cf_r, Cf_g, or Cf_b or overcoat layer Oc, and a patterned wiring layer. More specifically, one alignment mark 171 is constituted by an aggregate of five marks arrayed at equal intervals in the X direction.

A first mark positioned at the left end is constituted by a mark Cf_r1 obtained by patterning the color layer Cf_r in a square shape in plan view, and a mark 636b obtained by patterning the contact layer 636 in a square shape larger than the mark Cf_r1 in plan view such that the centers thereof coincide with each other.

In the figure, a second mark positioned at the right side of the first mark is constituted by a mark Cf_g1 obtained by patterning the color layer Cf_g in a square shape in plan view, and a mark 636c obtained by patterning the contact layer 636 in a square shape larger than the mark Cf_g1 in plan view such that the centers thereof coincide with each other.

A third mark positioned at the right side of the second mark is constituted by a mark Cf_b1 obtained by patterning the color layer Cf_b in a square shape in plan view, and a mark 636d obtained by patterning the contact layer 636 in a square shape larger than the mark Cf_b1 in plan view such that the centers thereof coincide with each other.

A fourth mark positioned at the right side of the third mark is constituted by a mark Oc1 obtained by patterning the overcoat layer Oc in a square shape in plan view, and a mark 636e obtained by patterning the contact layer 636 in a square shape larger than the mark Oc1 in plan view such that the centers thereof coincide with each other.

A fifth mark positioned at the right side of the fourth mark is constituted by a mark Oc2 obtained by patterning the overcoat layer Oc in a square shape in plan view and a mark 635b obtained by patterning the reflection layer 635 in a square shape larger than the mark Oc2 in plan view such that the centers thereof coincide with each other.

The marks Cf_r1, Cf_g1, Cf_b1, Oc1, and Oc2 are patterned to have the same size, and the marks 636b, 636c, 636d, 636e, and 635b are patterned to have the same size.

When the first to third marks are viewed from the Z direction, the color layer that is slightly smaller than a reflective mark having a square shape appears to overlap the reflective mark. Further, the overcoat layer Oc is colorless and transparent, and thus, only the reflective marks having the square shape are visible as the fourth mark and the fifth mark. Note that a reflectance of the reflection layer 635 is higher than a reflectance of the contact layer 636, and thus, the fifth mark may be visually recognized even when the fourth mark is not visually recognized.

FIG. 12 is a plan view illustrating a design rule of the light shielding member 181 with respect to the inspection terminal 151. Specifically, FIG. 12 is a diagram illustrating positional relationships between the inspection terminal 151 positioned at the left end among the inspection terminals 151 arrayed in the X direction and the color layers Cf_r, Cf_g, and Cf_b constituting the light shielding member 181 between the display unit 100 and the upper side Ue.

As illustrated in this figure, when a distance between the end portion of the inspection terminal 151 in the direction opposite to the Y direction and the end portion of the color layer Cf_r is defined as L1, a distance between the end portion of the color layer Cf_r and the end portion of the color layer Cf_b is defined as L2, and a distance between the end portion of the color layer Cf_b and the end portion of the color layer Cf_g is defined as L3, the color layers Cf_g, Cf_b, and Cf_r are overlapped in this order such that L1>L2, and L1>L3 are held.

That is, a margin is provided such that the light shielding member 181 formed by layering the three colors reliably covers the inspection terminal 151 even when a positional shift occurs when the color layers Cf_g, Cf_b, and Cf_r are formed.

Note that when the alignment mark 171 and the light shielding member 181 are brought close to each other, the color layer constituting the alignment mark 171 and the color layer constituting the light shielding member 181 may be coupled to each other due to a manufacturing error. In order to prevent this coupling, it is preferable that the alignment mark 171 and the light shielding member 181 be spaced apart from each other at a predetermined interval.

Thus, in the first embodiment, the two alignment marks 171 at the left and right ends of the upper side Ue that are close to the light shielding member 181 are positioned in the corner regions 183 where the light shielding member 181 is not provided.

According to the first embodiment, the inspection terminals 151 provided along the X direction are covered with the light shielding member 181, and thus, reflection of the inspection terminal 151s is suppressed in a display image at the display unit 100.

Note that the display unit 100 is generally horizontally long, that is, the X direction is longer than the Y direction, and thus, the inspection terminals 151 arrayed along the X direction are noticeably reflected. In other words, even when the inspection terminals 152 arrayed along the Y direction between the display unit 100 and the left side Le and the inspection terminals 153 arrayed along the Y direction between the display unit 100 and the right side Re are not shielded from light, reflection of the inspection terminals 152 and 153 is less noticeable than reflection of the inspection terminals 151.

Additionally, depending on an optical system for capturing a display image, the inspection terminals 152 and 153 arrayed along the Y direction do not need to be shielded from light in some cases.

Thus, in the first embodiment, only the inspection terminals 151 provided along the X direction are covered with the light shielding member 181. To add an extra precaution, the following second embodiment is desired.

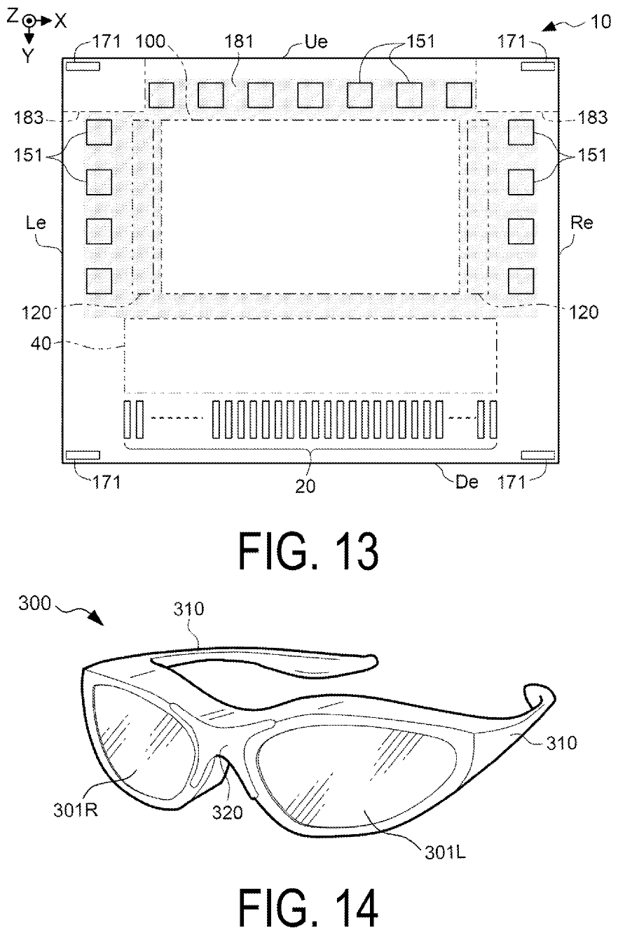

FIG. 13 is a plan view illustrating an arrangement of the light shielding member 181 in the electro-optical device 10 according to a second embodiment. In the second embodiment, the inspection terminals 152 and 153 arrayed along the Y direction are also covered with the light shielding member 181.

Thus, according to the second embodiment, not only the inspection terminals 151 provided along the X direction but also the inspection terminals 152 and 153 provided along the Y direction are covered with the light shielding member 181, which suppresses not only the reflection of the inspection terminals 151 but also the reflection of the inspection terminals 152 and 153 in the display image at the display unit 100.

Note that also in the second embodiment, in order to prevent the color layers from being coupled to each other due to a manufacturing error, the two alignment marks 171 at the left and right ends of the upper side Ue close to the light shielding member 181 are positioned in the corner regions 183 where the light shielding member 181 is not provided.

In the first embodiment and the second embodiment that have been described above (hereinafter referred to as “the embodiments and the like”), various modifications or applications are possible as follows.

In the embodiment, the color layers Cf_g, Cf_b, and Cf_r are layered at the sealing layer 71 in this order, but the layering order is not limited to this.

In addition, although the light shielding member 181 is constituted by the three colors of the color layers Cf_g, Cf_b, and Cf_r, when a separate process is allowed to be added, a member having a light shielding property such as a black matrix may be used.

In the embodiments and the like, the OLED 130 has been described as an example of the light-emitting element, but other light-emitting elements may be used. For example, as the light-emitting element, an LED, a mini LED, a micro LED, or the like may be used. Alternatively, instead of the light-emitting element, a liquid crystal element may be used as a display element.

In addition, the sub-pixel 11 includes the transistors 121 and 122, but may be separately provided with a transistor for diode-coupling the transistor 121 or a transistor for blocking a current flowing through the OLED 130 in order to compensate for a threshold voltage of the transistor 121.

Next, an electronic apparatus to which the electro-optical device 10 according to the above-described embodiments is applied will be described. The electro-optical device 10 is suitable for application with a small pixel and high definition display. Therefore, a head-mounted display will be described as an example of the electronic apparatus.

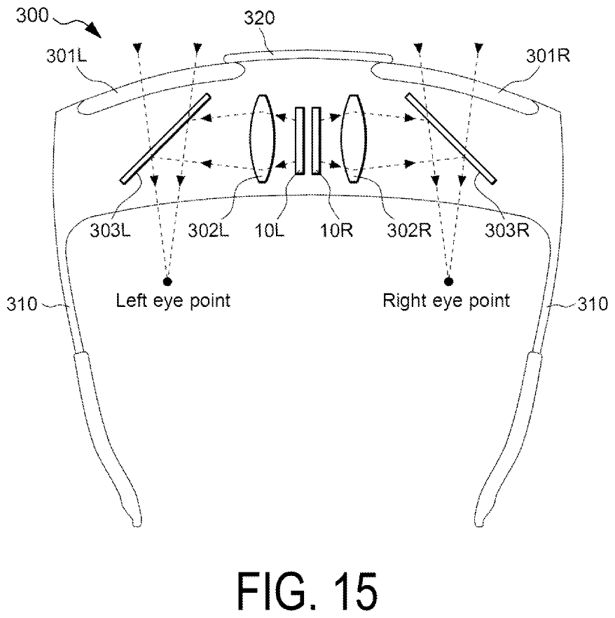

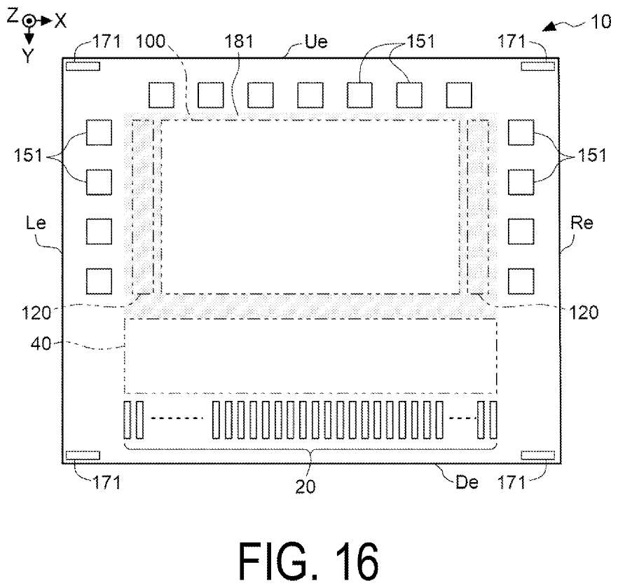

FIG. 14 is a diagram illustrating appearance of a head-mounted display, and FIG. 15 is a diagram illustrating an optical configuration of the head-mounted display.

As illustrated in FIG. 14, a head-mounted display 300 includes, in terms of appearance, temples 310, a bridge 320, and lenses 301L and 301R, as with typical eye glasses. In addition, as illustrated in FIG. 15, in the head-mounted display 300, an electro-optical device 10L for a left eye and an electro-optical device 10R for a right eye are provided in the vicinity of the bridge 320 and at the back side (the lower side in the drawing) of the lenses 301L and 301R.

An image display surface of the electro-optical device 10L is disposed to be at the left side in FIG. 15. Thus, a display image from the electro-optical device 10L is output through the optical lens 302L that is a capturing optical system in a nine o'clock direction in the drawing. A half mirror 303L reflects the display image from the electro-optical device 10L in a six o'clock direction, while the half mirror 303L transmits light incident from a twelve o'clock direction. An image display surface of the electro-optical device 10R is disposed on the right side opposite to the electro-optical device 10L. Thus, a display image from the electro-optical device 10R is output through the optical lens 302R that is a capturing optical system in a three o'clock direction in the drawing. A half mirror 303R reflects the display image from the electro-optical device 10R in a six o'clock direction, while the half mirror 303R transmits light incident from a twelve o'clock direction.

In this configuration, a wearer of the head-mounted display 300 can observe the display images from the electro-optical devices 10L and 10R in a see-through state in which the display images from the electro-optical devices 10L and 10R overlap scenery of the outside.

In addition, in the head-mounted display 300, in the images for both eyes with parallax, an image for a left eye is displayed at the electro-optical device 10L, and an image for a right eye is displayed at the electro-optical device 10R, and thus, it is possible to cause the wearer to sense the displayed images as an image displayed having a depth or a three-dimensional effect.

In addition to the head-mounted display 300, the electronic apparatus including the electro-optical device 10 can be applied to an electronic viewing finder in a video camera, a lens-exchangeable digital camera, or the like, a mobile information terminal, a wristwatch display, a light valve for a projection type projector, and the like.

Preferred aspects of the present disclosure are understood from the above description, as follows. In the following, in order to facilitate understanding of each of the aspects, the reference signs of the drawings are provided in parentheses for convenience, but the present disclosure is not intended to be limited to the illustrated aspects.

An electro-optical device (10) according to a first aspect includes a substrate having a rectangular shape in plan view, a display unit (100) provided with a light-emitting element (130) at the substrate, a plurality of first inspection terminals (151) provided between the display unit (100) and a second side (Ue) on an opposite side of the rectangular shape from a first side (De) in plan view at the substrate, and a light shielding member (181) provided so as to cover the plurality of first inspection terminals (151) in plan view.

According to the first aspect, since the first inspection terminals (151) are covered with the light shielding member (181), reflection of the first inspection terminals (151) is suppressed in a display image at the display unit (100).

In an electro-optical device (10) according to a second specific aspect of the first aspect, the light shielding member (181) is provided so as to surround the display unit (100) in plan view.

According to the second aspect, reflection of a peripheral wiring surrounding the display unit (100) is also suppressed.

In an electro-optical device (10) according to a third specific aspect of the second aspect, in the light shielding member (181), a first color layer (Cf_g) configured to color light emitted from a light-emitting element (130) in a first color, a second color layer (Cf_b) configured to color the light emitted from the light-emitting element (130) in a second color, and a third color layer (Cf_r) configured to color the light emitted from the light-emitting element (130) in a third color are layered in this order.

According to the third aspect, the first color layer (Cf_g), the second color layer (Cf_b), and the third color layer (Cf_r) that are used in the display unit (100) are also used as the light shielding member covering the first inspection terminals (151).

In an electro-optical device (10) according to a fourth specific aspect of the third aspect, in plan view, an end portion of the first color layer (Cf_g) constituting the light shielding member is positioned at an outer side than an end portion of the second color layer (Cf_b) constituting the light shielding member and an end portion of the third color layer (Cf_r) constituting the light shielding member, the end portion of the second color layer (Cf_b) constituting the light shielding member (181) is positioned at an outer side than the end portion of the third color layer (Cf_r) constituting the light shielding member (181), and the end portion of the third color layer (Cf_r) constituting the light shielding member (181) is positioned at an outer side than the plurality of first inspection terminals (151).

According to the fourth aspect, a margin is provided so that the light shielding member 181 formed by layering the three colors can reliably cover the inspection terminals 151 even when a positional shift of the color layers (Cf_g, Cf_b, and Cf_r) occurs in a manufacturing process.

In an electro-optical device (10) according to a fifth specific aspect of the fourth aspect, in plan view, a first distance (L1) between the end portion of the third color layer (Cf_r) constituting the light shielding member (181) and one first inspection terminal (151) of the plurality of first inspection terminals (151) is longer than a second distance (L2) between the end portion of the first color layer (Cf_r) and the end portion of the second color layer (Cf_b) that constitute the light shielding member (151) and a third distance (L3) between the end portion of the second color layer (Cf_b) and the end portion of the third color layer (Cf_r) that constitute the light shielding member (151).

In an electro-optical device (10) according to another sixth specific aspect of the first aspect, the light shielding member (181) is not provided in a corner region (183) corresponding to an included angle between the second side (Ue) and a third side (Le) coupled to the first side (De) of the rectangular shape at an outer side than a position where the plurality of first inspection terminals (151) are provided in plan view, and includes an alignment mark (171) in the corner region (183).

According to the sixth aspect, the color layers are prevented from being coupled to each other due to a manufacturing error.

In an electro-optical device (10) according to another seventh specific aspect of the first aspect, the substrate includes a plurality of second inspection terminals (152) provided outside the display unit (100) in plan view and between the display unit (100) and a third side (Le) coupled to the first side (De) of the rectangular shape, and a plurality of third inspection terminals (153) provided outside the display unit (100) in plan view and between the display unit (100) and a fourth side (Re) on an opposite side of the rectangular shape from the third side (Le), and the light shielding member (181) is provided so as to cover the plurality of second inspection terminals (152) and the plurality of third inspection terminals (153).

According to the seventh aspect, reflection of not only the inspection terminals 151 but also the inspection terminals 152 and 153 is suppressed.

An electronic apparatus (300) according to an eighth aspect includes the electro-optical device (10) according to any one of the first to eighth aspects. According to the eighth aspect, it is possible to perform high-quality display in which reflection of the first inspection terminals (151) is suppressed.

What is claimed is:

1. An electro-optical device comprising:
a substrate having a rectangular shape in plan view;
a display unit provided with a light-emitting element at the substrate;
a plurality of first inspection terminals provided, in plan view, between the display unit and a second side that is on an opposite side of the rectangular shape from a first side, at the substrate; and
a light shielding member provided that covers the plurality of first inspection terminals in plan view.

2. The electro-optical device according to claim 1, wherein
the light shielding member is provided that surrounds the display unit in plan view.

3. The electro-optical device according to claim 2, wherein
in the light shielding member,
a first color layer configured to color light emitted from a light-emitting element in a first color, a second color layer configured to color the light emitted from the light-emitting element in a second color, and a third color layer configured to color the light emitted from the light-emitting element in a third color are layered in this order.

4. The electro-optical device according to claim 3, wherein
in plan view,
an end portion of the first color layer forming the light shielding member is
positioned on an outer side than an end portion of the second color layer forming the light shielding member and an end portion of the third color layer forming the light shielding member,
the end portion of the second color layer forming the light shielding member is
positioned on an outer side than the end portion of the third color layer forming the light shielding member, and
the end portion of the third color layer forming the light shielding member is positioned on an outer side than the plurality of first inspection terminals.

5. The electro-optical device according to claim 4, wherein
in plan view
a first distance between the end portion of the third color layer forming the light shielding member and one first inspection terminal of the plurality of first inspection terminals is longer than
a second distance between the end portion of the first color layer forming the light shielding member and the end portion of the second color layer forming the light shielding member, and a third distance between the end portion of the second color layer forming the light shielding member and the end portion of the third color layer forming the light shielding member.

6. The electro-optical device according to claim 1, wherein
in plan view, the light shielding member is not provided at a corner region corresponding to an included angle between the second side and a third side coupled to the first side of the rectangular shape,
the corner region being positioned outside a position where the plurality of first inspection terminals are provided, and
the corner region includes an alignment mark.

7. The electro-optical device according to claim 1, wherein
the substrate includes
a plurality of second inspection terminals provided, in plan view, outside the display unit and between the display unit and a third side coupled to the first side of the rectangular shape, and
a plurality of third inspection terminals provided, in plan view, outside the display unit and between the display unit and a fourth side that is on an opposite side of the rectangular shape from the third side, and
the light shielding member is provided so as to cover the plurality of second inspection terminals and the plurality of third inspection terminals.

8. An electronic apparatus comprising
the electro-optical device according to claim 1.
